(19) United States
(12) Patent Application Publication
(10) Pub. No.: US 2024/0194475 A1
(43) Pub. Date: Jun. 13, 2024

(54) SUBSTRATE PROCESSING METHOD, SUBSTRATE PROCESSING APPARATUS, AND DRY PROCESSING LIQUID

(71) Applicants: SCREEN Holdings Co., Ltd., Kyoto (JP); DAIKIN INDUSTRIES, LTD., Osaka (JP)

(72) Inventors: Takaaki ISHIZU, Kyoto (JP); Kenji KOBAYASHI, Kyoto (JP); Takashi OTA, Kyoto (JP); Takashi NAMIKAWA, Osaka (JP); Kazuki HOSODA, Osaka (JP)

(21) Appl. No.: 18/555,487

(22) PCT Filed: Mar. 23, 2022
(86) PCT No.: PCT/JP2022/013555

§ 371 Date: Oct. 13, 2023

(30) Foreign Application Priority Data
Apr. 16, 2021 (JP) 2021-069639

(51) Int. Cl. H01L 21/02; H01L 21/306; H01L 21/67

(52) U.S. Cl. CPC H01L 21/02057; H01L 21/30604; H01L 21/67023

(57) ABSTRACT

A substrate processing method includes supplying a chemical solution to a surface of a substrate (step S11), supplying a rinse liquid to the surface of the substrate after step S11 (step S12), bringing a heated dry processing liquid to the surface of the substrate after step S12 (step S14), and drying the substrate by removing the dry processing liquid from the surface of the substrate (step S15). The dry processing liquid has a lower surface tension than the rinse liquid. The boiling point of the dry processing liquid is higher than the boiling point of the rinse liquid. The dry processing liquid that comes in contact with the surface of the substrate in step S14 has a temperature that is a predetermined contact temperature higher than or equal to the boiling point of the rinse liquid and lower than the boiling point of the dry processing liquid.

### TECHNICAL FIELD

The present invention relates to a technique for processing substrates, and a dry processing liquid used for substrate processing.

### CROSS-REFERENCE TO RELATED APPLICATIONS

This application claims priority benefit of Japanese Patent Application No. JP2021-069639 filed in the Japan Patent Office on Apr. 16, 2021, the entire disclosure of which is incorporated herein by reference.

### BACKGROUND ART

A conventional process for manufacturing semiconductor substrates (hereinafter, simply referred to as “substrates”) involves a variety of processing to be performed on substrates. For example, chemical processing is performed by supplying a chemical solution such as an etchant to surfaces of the substrates. After completion of the chemical processing, rinsing processing is performed by supplying a rinse liquid to the substrates, and thereafter dry processing is performed on the substrates.

In the case where fine patterns are formed on a surface of a substrate, the surface tension of a liquid acts on the positions of contact between the patterns and the liquid level existing between the patterns (i.e., interfaces between the liquid and air). Since water that is typically used as the aforementioned rinse liquid has a high surface tension, the patterns may be destroyed during the dry processing performed after the rinsing processing.

In view of this, Japanese Patent Application Laid-Open No. 2017-117954 (Document 1) discloses a technique for supplying isopropyl alcohol (IPA) having a lower surface tension than water onto a substrate after rinsing processing so as to replace the water with the IPA and then removing the IPA from above the substrate before dry processing on the substrate, in order to prevent pattern destruction. Document 1 also gives examples of the liquid that can be used instead of the IPA, such as hydrofluoroether (HFE), methanol, and ethanol that have a lower surface tension than water.

Japanese Patent Application Laid-Open No. 2013-157625 (Document 2) discloses a technique for supplying IPA onto a substrate after rinsing processing so as to replace water with the IPA, supplying a water-repellent onto the substrate so as to provide the upper surface of the substrate with water repellency, further supplying IPA onto the substrate so as to replace the water-repellent with the IPA, and then removing the IPA from above the surface so as to perform dry processing on the substrate, in order to prevent pattern destruction. Document 2 also gives examples of the liquid that can be used instead of the IPA, such as HFE, hydrofluorocarbon (HFC), methanol, and ethanol that have a lower surface tension than water.

With an increase in the aspect ratios of patterns on a substrate in recent years, the patterns are becoming easier to destroy, and therefore there is demand to further prevent pattern destruction during dry processing.

### SUMMARY OF THE INVENTION

The present invention is intended for a substrate processing method for processing substrates, and it is an object of the present invention to prevent pattern destruction during dry processing.

A substrate processing method according to one preferable embodiment of the present invention includes a) supplying a chemical solution to a surface of a substrate, b) supplying a rinse liquid to the surface of the substrate after the operation a), c) bringing a heated dry processing liquid into contact with the surface of the substrate after the operation b), and d) drying the substrate by removing the dry processing liquid from the surface of the substrate after the operation c). The dry processing liquid has a lower surface tension than the rinse liquid. A boiling point of the dry processing liquid is higher than a boiling point of the rinse liquid. The dry processing liquid that comes in contact with the surface of the substrate in the operation c) has a temperature that is a predetermined contact temperature higher than or equal to the boiling point of the rinse liquid and lower than the boiling point of the dry processing liquid.

According to the substrate processing method, it is possible to prevent pattern destruction during dry processing.

Preferably, the substrate processing method may further include e) removing molecules of the dry processing liquid adsorbed on the surface of the substrate by heating the substrate after the operation d).

Preferably, the operation d) and the operation e) may be conducted in one chamber.

Preferably, the substrate processing method may further include supplying a substitution liquid to the surface of the substrate and replacing the rinse liquid that is in contact with the surface of the substrate with the substitution liquid between the operation b) and the operation c). In the operation c), the dry processing liquid replaces the substitution liquid that is in contact with the surface of the substrate.

Preferably, in the operation c), the dry processing liquid that is preheated to the contact temperature may be supplied to the surface of the substrate.

Preferably, in the operation c), a temperature of the dry processing liquid may be increased to the contact temperature by heating the dry processing liquid that is in contact with the surface of the substrate.

Preferably, a difference between the contact temperature and the boiling point of the dry processing liquid may be less than or equal to 65° C.

Preferably, in the operation c), a contact time of the dry processing liquid having the contact temperature with the surface of the substrate may be 10 seconds or more.

Preferably, the dry processing liquid may contain fluorine-containing alcohol.

Preferably, the fluorine-containing alcohol may have —CF₂H at a terminal.

Preferably, the fluorine-containing alcohol may have —CF₃ at a terminal.

Preferably, the number of carbons (C) contained in a molecular formula of the fluorine-containing alcohol may be 4 or more.

The present invention is also intended for a substrate processing apparatus for processing substrates. A substrate processing apparatus according to one preferable embodiment of the present invention includes a chemical solution supplier that supplies a chemical solution to a surface of a substrate, a rinse liquid supplier that supplies a rinse liquid to the surface of the substrate, a dry processing liquid supplier that supplies a heated dry processing liquid to the surface of the substrate, and a dry processing unit that dries the substrate by removing the dry processing liquid from the surface of the substrate. The dry processing liquid has a lower surface tension than the rinse liquid. A boiling point of the dry processing liquid is higher than a boiling point of the rinse liquid. The dry processing liquid that comes in contact with the surface of the substrate has a temperature that is a predetermined contact temperature higher than or equal to the boiling point of the rinse liquid and lower than the boiling point of the dry processing liquid.

Preferably, the dry processing liquid may contain fluorine-containing alcohol.

The present invention is also intended for a dry processing liquid for use in substrate processing. A substrate processing method using a dry processing liquid according to one preferable embodiment of the present invention includes a) supplying a chemical solution to a surface of a substrate, b) supplying a rinse liquid to the surface of the substrate after the operation a), c) bringing the dry processing liquid that is heated, into contact with the surface of the substrate after the operation b), and d) drying the substrate by removing the dry processing liquid from the surface of the substrate after the operation c). The dry processing liquid contains fluorine-containing alcohol. The dry processing liquid has a lower surface tension than the rinse liquid. A boiling point of the dry processing liquid is higher than a boiling point of the rinse liquid. The dry processing liquid that comes in contact with the surface of the substrate in the operation c) has a temperature that is a predetermined contact temperature higher than or equal to the boiling point of the rinse liquid and lower than the boiling point of the dry processing liquid.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a plan view showing a substrate processing system according to a first embodiment.

FIG. 2 is a side view showing a configuration of a substrate processing apparatus.

FIG. 3 shows a configuration of a controller.

FIG. 4 is a block diagram showing a gas-liquid supplier.

FIG. 5 is a flowchart of substrate processing.

FIG. 6A schematically shows molecules in a first dry processing liquid adsorbed on a substrate.

FIG. 6B schematically shows molecules in a second dry processing liquid adsorbed on a substrate.

FIG. 6C schematically shows molecules in a third dry processing liquid adsorbed on a substrate.

FIG. 7 shows pattern destruction rates.

FIG. 8 shows pattern destruction rates.

FIG. 9 is a plan view showing a substrate processing system according to a second embodiment.

FIG. 10 is a side view showing a first processing unit and a lifter.

### DESCRIPTION OF EMBODIMENTS

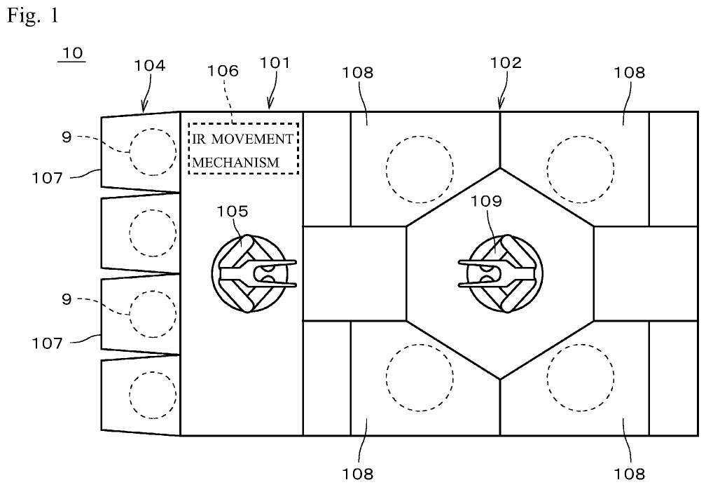

FIG. 1 is a diagrammatic plan view showing a layout of a substrate processing system 10 that includes a substrate processing apparatus according to a first embodiment of the present invention. The substrate processing system 10 is a system for processing semiconductor substrates 9 (hereinafter, simply referred to as “substrates 9”). The substrate processing system 10 includes an indexer block 101 and a processing block 102 that is coupled to the indexer block 101.

The indexer block 101 includes a carrier holder 104, an indexer robot 105 (i.e., substrate transport means), and an IR movement mechanism 106. The carrier holder 104 holds a plurality of carriers 107, each capable of housing a plurality of substrates 9. The carriers 107 (e.g., FOUPs) are held by the carrier holder 104 while being aligned in a horizontal carrier alignment direction (i.e., in the up-down direction in FIG. 1). The IR movement mechanism 106 moves the indexer robot 105 in the carrier alignment direction. The indexer robot 105 performs export operations of transporting the substrates 9 out of the carriers 107 and import operations of transporting the substrates 9 into the carriers 107 held by the carrier holder 104. The substrates 9 are transported in a horizontal position by the indexer robot 105.

Meanwhile, the processing block 102 includes a plurality of (e.g., four or more) processing units 108, each processing the substrates 9, and a center robot 109 (i.e., substrate transport means). The processing units 108 are arranged to surround the center robot 109 in plan view. The processing units 108 perform a variety of processing on the substrates 9. A substrate processing apparatus described later is one of the processing units 108. The center robot 109 performs import operations of transporting the substrates 9 into the processing units 108 and export operations of transporting the substrates 9 out of the processing units 108. The center robot 109 further transports the substrates 9 between the processing units 108. The substrates 9 are transported in a horizontal position by the center robot 109. The center robot 109 receives the substrates 9 from the indexer robot 105 and transfers the substrates 9 to the indexer robot 105.

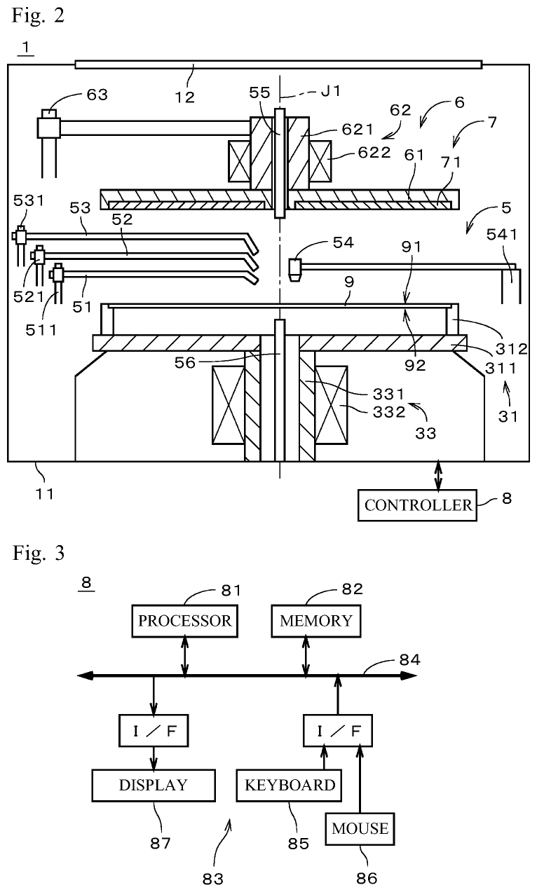

FIG. 2 is a side view showing a configuration of the substrate processing apparatus 1. The substrate processing apparatus 1 is a single wafer processing apparatus for processing the substrates 9 one by one. The substrate processing apparatus 1 performs liquid processing by supplying a processing liquid to the substrates 9. FIG. 2 shows part of the configuration of the substrate processing apparatus 1 in cross section.

The substrate processing apparatus 1 includes a substrate holder 31, a substrate rotation mechanism 33, a gas-liquid supplier 5, an interrupter 6, a substrate heater 7, a controller 8, and a chamber 11. Constituent elements such as the substrate holder 31, the substrate rotation mechanism 33, the interrupter 6, and the substrate heater 7 are housed in the internal space of the chamber 11. The chamber 11 has a canopy portion provided with an airflow former 12 that supplies gas to the internal space to form a downward airflow (so-called a down flow). An example of the airflow former 12 to be used may be a fan filter unit (FFU).

The controller 8 is arranged outside the chamber 11 and controls constituent elements such as the substrate holder 31, the substrate rotation mechanism 33, the gas-liquid supplier 5, the interrupter 6, and the substrate heater 7. As shown in FIG. 3, the controller 8 may, for example, be an ordinary computer system that includes a processor 81, memory 82, an input-output device 83, and a bus 84. The bus 84 is a signal circuit that connects the processor 81, the memory 82, and the input-output device 83. The memory 82 stores programs and various types of information. The processor 81 executes a variety of processing (e.g., numerical calculation) using, for example, the memory 82 and in accordance with the programs or the like stored in the memory 82. The input-output device 83 may include, for example, a keyboard 85 and a mouse 86 that receive input from an operator, a display 87 that displays outputs or the like received from the processor 81, and a transmitter that transmits outputs or the like received from the processor 81. Note that the controller 8 may, for example, be a programmable logic controller (PLC) or a circuit board. The controller 8 may include a plurality of arbitrary configurations of, for example, a computer system, a PLC, and a circuit board.

The substrate holder 31 and the substrate rotation mechanism 33 shown in FIG. 2 each are a part of a spin chuck that holds and rotates a substrate 9. The substrate holder 31 faces a main surface on the lower side (hereinafter, also referred to as the “lower surface 92”) of the substrate 9 in a horizontal position and holds the substrate 9 from the underside. For example, the substrate holder 31 may be a mechanical chuck that mechanically supports the substrate 9. The substrate holder 31 includes a base 311 and a plurality of chucks 312. The base 311 is an approximately disk-like member centered on a central axis J1 pointing in the up-down direction. The substrate 9 is disposed above the base 311. The base 311 has a diameter slightly larger than the diameter of the substrate 9.

The chucks 312 are arranged on the outer peripheral portion of the upper surface of the base 311 in a circumferential direction centered on the central axis J1 (hereinafter, also simply referred to as the “circumferential direction”). For example, the chucks 312 may be arranged at approximately equiangular intervals in the circumferential direction. In the substrate holder 31, the chucks 312 hold the outer edge portion of the substrate 9. Note that the substrate holder 31 may be any other chuck having a different structure, such as a vacuum chuck that adsorbs on and holds a central portion of the lower surface 92 of the substrate 9.

The substrate rotation mechanism 33 is arranged below the substrate holder 31. The substrate rotation mechanism 33 rotates the substrate 9, together with the substrate holder 31, about the central axis J1. The substrate rotation mechanism 33 includes a shaft 331 and a motor 332. The shaft 331 is an approximately cylindrical member centered on the central axis J1. The shaft 331 extends in the up-down direction and is connected to a central portion of the lower surface of the base 311 of the substrate holder 31. The motor 332 is an electric rotary motor that rotates the shaft 331. Note that the substrate rotation mechanism 33 may be any other motor having a different structure (e.g., a hollow motor).

The gas-liquid supplier 5 supplies a plurality of types of processing liquids individually to the substrate 9 and performs liquid processing on the substrate 9. The gas-liquid supplier 5 also supplies an inert gas toward the substrate 9. The plurality of types of processing liquids include a chemical solution, a rinse liquid, a substitution liquid, and a dry processing liquid that are described later.

The gas-liquid supplier 5 includes a first nozzle 51, a second nozzle 52, a third nozzle 53, and a fourth nozzle 54. Each of the first, second, third, and fourth nozzles 51, 52, 53, and 54 ejects a different type of processing liquid toward the main surface on the upper side (hereinafter, also referred to as the “upper surface 91”) of the substrate 9 from above the substrate 9. The upper surface 91 of the substrate 9 has a fine pattern formed thereon in advance. This pattern may, for example, be a pattern having a high aspect ratio. For example, the first, second, third, and fourth nozzles 51, 52, 53, and 54 may be formed of a resin having high chemical resistance such as Teflon (registered trademark).

In the gas-liquid supplier 5, two or more of the first, second, third, and fourth nozzles 51, 52, 53, and 54 may be merged into a single shared nozzle. In this case, the shared nozzle functions as each of the two or more nozzles. The shared nozzle may include therein an individual passage for each type of processing liquid, or may include a common passage passing a plurality of types of processing liquids. Moreover, each of the first, second, third, and fourth nozzles 51, 52, 53, and 54 may be configured by two or more nozzles.

The gas-liquid supplier 5 further includes a first-nozzle movement mechanism 511, a second-nozzle movement mechanism 521, a third-nozzle movement mechanism 531, and a fourth-nozzle movement mechanism 541. The first-nozzle movement mechanism 511 moves the first nozzle 51 approximately horizontally between a supply position located above the substrate 9 and a retracted position located outward of the outer edge of the substrate 9 in a radial direction centered on the central axis J1 (hereinafter, also simply referred to as the radial direction”). The second-nozzle movement mechanism 521 moves the second nozzle 52 approximately horizontally between a supply position located above the substrate 9 and a retracted position located outward of the outer edge of the substrate 9 in the radial direction. The third-nozzle movement mechanism 531 moves the third nozzle 53 approximately horizontally between a supply position located above the substrate 9 and a retracted position located outward of the outer edge of the substrate 9 in the radial direction. The fourth-nozzle movement mechanism 541 moves the fourth nozzle 54 approximately horizontally between a supply position located above the substrate 9 and a retracted position located outward of the outer edge of the substrate 9 in the radial direction. For example, the first-nozzle movement mechanism 51 may include any of an electric linear motor, an air cylinder, and a ball screw and an electric rotary motor that are connected to the first nozzle 51. The same applies to the second-nozzle movement mechanism 521, the third-nozzle movement mechanism 531, and the fourth-nozzle movement mechanism 541.

The interrupter 6 includes a top plate 61, a top-plate rotation mechanism 62, and a top-plate movement mechanism 63. The top plate 61 is an approximately disk-like member centered on the central axis J1, and is arranged above the substrate holder 31. The top plate 61 has a diameter slightly larger than the diameter of the substrate 9. The top plate 61 is an opposing portion that faces the upper surface 91 of the substrate 9 and serves as a shielding plate that shields the space above the substrate 9.

The top-plate rotation mechanism 62 is arranged above the top plate 61. The top-plate rotation mechanism 62 rotates the top plate 61 about the central axis J1. The top-plate rotation mechanism 62 includes a shaft 621 and a motor 622. The shaft 621 is an approximately cylindrical member centered on the central axis J1. The shaft 621 extends in the up-down direction and is connected to a central portion of the upper surface of the top plate 61. The motor 622 is an electric rotary motor that rotates the shaft 621. Note that the top-plate rotation mechanism 62 may be any other motor having a different structure (e.g., a hollow motor).

The top-plate movement mechanism 63 moves the top plate 61 in the up-down direction above the substrate 9. For example, the top-plate movement mechanism 63 may include any of an electric linear motor, an air cylinder, and a ball screw and an electric rotary motor that are connected to the shaft 621.

The substrate heater 7 includes a light irradiator 71 that irradiates the substrate 9 with light to heat the substrate 9. In the example shown in FIG. 1, the light irradiator 71 is provided on the top plate 61 and heats the substrate 9 by applying light from the lower surface of the top plate 61 toward the upper surface 91 of the substrate 9. For example, the light irradiator 71 may include a plurality of light emitting diodes (LEDs) built in the lower surface of the top plate 61.

For example, these LEDs may be arranged approximately uniformly in an approximately circular ring-shaped region centered on the central axis J1 in the lower surface of the top plate 61 and apply light to the entire upper surface 91 of the substrate 9. The light irradiator 71 may be provided separately from the top plate 61 and may apply light toward the upper surface 91 of the substrate 9. As another alternative, the light irradiator 71 may heat the substrate 9 by irradiating the lower surface 92 of the substrate 9 with light. In this case, the light irradiator 71 may be provided in the base 311 of the substrate holder 31. The substrate heater 7 may heat the substrate 9 by a different method other than photoirradiation (e.g., with a heating-wire heater or by supply of a heated fluid).

The gas-liquid supplier 5 further includes an upper nozzle 55 and a lower nozzle 56. The upper nozzle 55 is arranged inside the shaft 621 of the top-plate rotation mechanism 62. The lower end portion of the upper nozzle 55 protrudes downward from an opening formed in the central portion of the top plate 61 and faces the central portion of the upper surface 91 of the substrate 9 in the up-down direction. The upper nozzle 55 supplies an inert gas toward the upper surface 91 of the substrate 9. The lower nozzle 56 is arranged inside the shaft 331 of the substrate rotation mechanism 33. The upper end portion of the lower nozzle 56 protrudes upward from an opening formed in the central portion of the base 311 of the substrate holder 31 and faces the central portion of the lower surface 92 of the substrate 9 in the up-down direction. In the case where the lower surface 92 of the substrate 9 needs liquid processing, the lower nozzle 56 supplies a processing liquid toward the lower surface 92 of the substrate 9. Alternatively, the lower nozzle 56 may be used to supply gas (e.g., heated inert gas) to the lower surface 92 of the substrate 9.

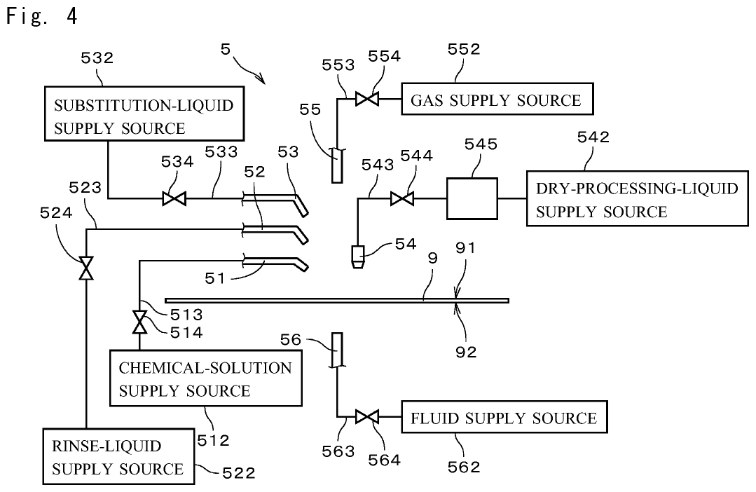

FIG. 4 is a block diagram showing the gas-liquid supplier 5 of the substrate processing apparatus 1. The first nozzle 51 is connected to a chemical-solution supply source 512 via piping 513 and a valve 514. When the valve 514 is opened under the control of the controller 8 (see FIG. 2), a chemical solution used for chemical processing on the substrate 9 is ejected from the tip end of the first nozzle 51 toward the upper surface 91 of the substrate 9. That is, the first nozzle 51 serves as a chemical solution supplier that supplies a chemical solution to the substrate 9. The chemical solution may, for example, be a hydrofluoric acid. The chemical solution may be a liquid other than a hydrofluoric acid. Examples of the chemical solution include liquids, each including at least one of a sulfuric acid, an acetic acid, a nitric acid, a hydrochloric acid, a hydrofluoric acid, an ammonia solution, a hydrogen peroxide solution, an organic acid (e.g., a citric acid or an oxalic acid), organic alkali (e.g., tetramethylammonium hydroxide: TMAH), a surfactant, and a corrosion inhibitor.

The second nozzle 52 is connected to a rinse-liquid supply source 522 via piping 523 and a valve 524. When the valve 524 is opened under the control of the controller 8, the rinse liquid used for rinsing processing on the substrate 9 is ejected from the tip end of the second nozzle 52 toward the upper surface 91 of the substrate 9. That is, the second nozzle 52 serves as a rinse liquid supplier that supplies a rinse liquid to the substrate 9. The rinse liquid may, for example, be de-ionized water (DIW). The rinse liquid may be a liquid other than DIW. For example, the rinse liquid may be any of carbonated water, field ionized water, hydrogen water, ozonated water, and hydrochloride water having a dilution concentration of approximately 10 ppm to 100 ppm.

The third nozzle 53 is connected to a substitution-liquid supply source 532 via piping 533 and a valve 534. When the valve 534 is opened under the control of the controller 8, the substitution liquid used for replacement processing on the rinse liquid is ejected from the tip end of the third nozzle 53 toward the upper surface 91 of the substrate 9. That is, the third nozzle 53 serves as a substitution-liquid supplier that supplies a substitution liquid to the substrate 9. The replacement processing is processing for supplying a substitution liquid to the substrate 9 to replace the rinse liquid on the substrate 9 with the substitution liquid. The substitution liquid to be used may be a liquid that has a relatively high affinity with the aforementioned rinse liquid and also has a relatively high affinity with a dry processing liquid, which will be described later. The substitution liquid may, for example, be isopropyl alcohol (IPA). The substitution liquid may be a liquid other than IPA. For example, the substitution liquid may be methanol or ethanol.

The fourth nozzle 54 is connected to a dry-processing-liquid supply source 542 via piping 543, a valve 544, and a liquid heater 545. The liquid heater 545 preheats a dry processing liquid used for dry processing on the substrate 9 as necessary. The liquid heater 545 may, for example, be a heating-wire heater. When the valve 544 is opened under the control of the controller 8, a dry processing liquid is ejected from the tip end of the fourth nozzle 54 toward the upper surface 91 of the substrate 9. That is, the fourth nozzle 54 serves as a dry processing liquid supplier that supplies a heated dry processing liquid to the substrate 9 so as to bring the dry processing liquid to the substrate 9.

Preferably, the dry processing liquid may contain fluorine-containing alcohol. The fluorine-containing alcohol may, for example, be fluorine-containing alcohol having a “difluoromethyl group (—CF₂H)” or a “trifluoromethyl group (—CF₃)” at the terminal. The terminal as used herein refers to the end of a molecule of fluorine-containing alcohol on the opposite side to a “hydroxyl group (—OH)” of the fluorinated alkyl chain. In the case where the fluorinated alkyl chain is branched, the terminal as used herein may be the terminal of the main chain, or may be the terminal of a branched chain. The dry processing liquid has a lower surface tension than the aforementioned rinse liquid. The boiling point of the dry processing liquid is lower than the boiling point of the rinse liquid. Moreover, the dry processing liquid is a liquid that does not chemically react with the surface of the substrate 9 and the aforementioned pattern formed on the substrate 9. The number of carbons (C) contained in the molecular formula of the aforementioned fluorine-containing alcohol may preferably be three or more and more preferably four or more. The number of carbons (C) contained in the molecular formula of fluorine-containing alcohol may also preferably be eight or less and more preferably seven or less. If the number of carbons (C) is seven or less, it is possible to avoid becoming a target for perfluorooctanoic acid (PFOA) restrictions.

The dry processing liquid may, for example, be a liquid that contains 1H, 1H, 7H-Dodecafluoroheptanol (represented by a rational formula of H(CF₂)₆CH₂OH) as fluorine-containing alcohol (this liquid is hereinafter also referred to as the “first dry processing liquid”). Alternatively, the dry processing liquid may be a liquid that contains 1H, 1H, 3H-Tetrafluoropropanol (represented by a rational formula of CHF₂CF₂CH₂OH) as fluorine-containing alcohol (this liquid is hereinafter also referred to as the “second dry processing liquid”). As another alternative, the dry processing liquid may be a liquid that contains 2-(Perfluorohexyl)ethanol (represented by a rational formula of F(CF₂)₆CH₂CH₂OH) as fluorine-containing alcohol (this liquid is hereinafter also referred to as the “third dry processing liquid”). The first and second dry processing liquids contain fluorine-containing alcohol that has —CF₂H at the terminal. The third dry processing liquid contains fluorine-containing alcohol that has —CF₃ at the terminal.

The dry processing liquid described above may be a liquid other than the first, second, and third dry processing liquids. The dry processing liquid may be one kind of liquid, or may be a mixed solution that contains two or more kinds of liquids. Preferably, the dry processing liquid may contain at least one or more liquids selected from the group consisting of the first, second, and third dry processing liquids.

In the present embodiment, the first dry processing liquid is substantially composed of only 1H, 1H, 7H-Dodecafluoroheptanol. The second dry processing liquid is substantially composed of only 1H, 1H, 3H-Tetrafluoropropanol. The third dry processing liquid is substantially composed of only 2-(Perfluorohexyl)ethanol. The first dry processing liquid has a molecular weight of 332.1 (g/mol), a specific gravity (d20) of 1.76(g/cm³), and a boiling point of 169° C. to 170° C. The second dry processing liquid has a molecular weight of 132.1 (g/mol), a specific gravity (d20) of 1.49 (g/cm³), and a boiling point of 109° C. to 110° C. The third dry processing liquid has a molecular weight of 364.1 (g/mol), a specific gravity (d20) of 1.68 (g/cm³), and a boiling point of 190° C. to 200° C. All of the first, second, and third dry processing liquids are available from Daikin Industries, Ltd.

In the substrate processing apparatus 1, when the chemical solution is supplied from the first nozzle 51 to the substrate 9, the first nozzle 51 is located at its supply position, and the second, third, and fourth nozzles 52, 53, and 54 are located at their retracted positions. When the rinse liquid is supplied from the second nozzle 52 to the substrate 9, the second nozzle 52 is located at its supply position, and the first, third, and fourth nozzles 51, 53, and 54 are located at their retracted positions. When the substitution liquid is supplied from the third nozzle 53 to the substrate 9, the third nozzle 53 is located at its supply position, and the first, second, and fourth nozzles 51, 52, and 54 are located at their retracted positions. When the dry processing liquid is supplied from the fourth nozzle 54 to the substrate 9, the fourth nozzle 54 is located at its supply position, and the first, second, and third nozzles 51, 52, and 53 are located at their retracted positions.

The upper nozzle 55 is connected to a gas supply source 552 via piping 553 and a valve 554. When the valve 554 is opened under the control of the controller 8, an inert gas such as a nitrogen (N₂) gas is supplied from the tip end of the upper nozzle 55 to the space between the upper surface 91 of the substrate 9 and the lower surface of the top plate 61 (see FIG. 2). The inert gas may be a gas other than a nitrogen gas (e.g., argon (Ar) gas).

The lower nozzle 56 is connected to a fluid supply source 562 via piping 563 and a valve 564. When the valve 564 is opened under the control of the controller 8, a fluid is ejected from the tip end of the lower nozzle 56 to the central portion of the lower surface 92 of the substrate 9. The fluid supplied from the lower nozzle 56 may, for example, be liquid or gas. The fluid may also be a liquid that is heated to a temperature higher than ordinary temperatures (e.g., 25° C.).

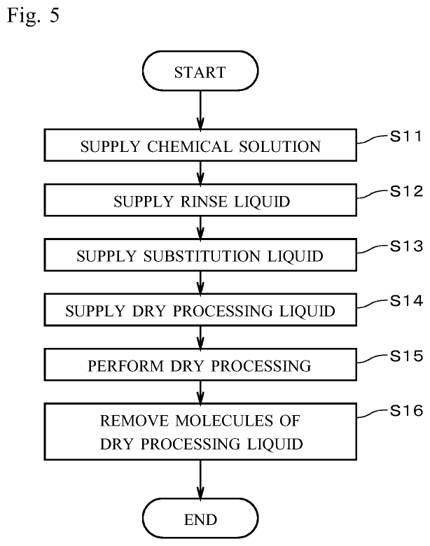

Next, a procedure for processing the substrates 9 in the substrate processing apparatus 1 in FIG. 2 will be described with reference to FIG. 5. In the substrate processing apparatus 1, firstly, a substrate 9 with a fine pattern formed in advance on the upper surface 91 is held in a horizontal position by the substrate holder 31. Then, the supply of an inert gas (e.g., a nitrogen gas) from the upper nozzle 55 is started. The flow rate of the inert gas supplied from the upper nozzle 55 may, for example, be 10 liters/min. Moreover, the substrate rotation mechanism 33 starts to rotate the substrate 9. The rotational speed of the substrate 9 may, for example, be in the range of 800 rpm to 1000 rpm. Furthermore, the top-plate rotation mechanism 62 starts to rotate the top plate 61. The rotational direction and speed of the top plate 61 may, for example, be the same as the rotational direction and speed of the substrate 9. The position of the top plate 61 in the up-down direction is such a position (hereinafter, also referred to as a “first processing position”) that allows the first nozzle 51 or the like to be arranged in the space between the top plate 61 and the substrate 9.

With the first nozzle 51 located at the supply position, the chemical solution (e.g., a hydrofluoric acid) is supplied from the first nozzle 51 to the central portion of the upper surface 91 of the substrate 9 (step S11). The chemical solution supplied to the central portion of the substrate 9 spreads radially outward from the central portion of the substrate 9 by centrifugal force caused by the rotation of the substrate 9 and is applied to the entire upper surface 91 of the substrate 9. The chemical solution is dispersed or flows radially outward from the outer edge of the substrate 9. The chemical solution dispersed or flowing out from above the substrate 9 is received and collected by, for example, a cup (not shown). The same can be said for the other processing liquids. The substrate processing apparatus 1 performs chemical processing on the substrate 9 by applying the chemical solution to the substrate 9 for a predetermined time.

When the chemical processing on the substrate 9 has completed, the first nozzle 51 that has stopped the ejection of the chemical solution is moved from its supply position to its retracted position, and the second nozzle 52 is moved from its retracted position to its supply position. Then, the rinse liquid (e.g., DIW) is supplied from the second nozzle 52 to the central portion of the upper surface 91 of the substrate 9 (step S12). The rotational speed of the substrate 9 during the supply of the rinse liquid may, for example, be in the range of 800 rpm to 1200 rpm. The rinse liquid supplied to the central portion of the substrate 9 is moved radially outward from the central portion of the substrate 9 by centrifugal force caused by the rotation of the substrate 9, and applied to the entire upper surface 91 of the substrate 9. The chemical solution on the substrate 9 is moved radially outward by the rinse liquid and removed from above the substrate 9. In the substrate processing apparatus 1, the rinsing processing on the substrate 9 is performed by applying the rinse liquid to the substrate 9 for a predetermined time.

When the chemical solution is removed from above the substrate 9 (i.e., when the chemical solution on the substrate 9 is wholly replaced with the rinse liquid), the rotational speed of the substrate 9 is reduced. In this way, a liquid membrane of the rinse liquid is formed and maintained on the upper surface 91 of the substrate 9. The rotational speed of the substrate 9 may, for example, be 10 rpm. The liquid membrane of the rinse liquid covers the entire upper surface 91 of the substrate 9. When the liquid membrane of the rinse liquid is formed, the ejection of the rinse liquid from the second nozzle 52 is stopped, and the second nozzle 52 is retracted from its supply position to its retracted position. The rotational speed of the substrate 9 may be any rotational speed that does not cause drying of the upper surface 91 of the substrate 9 and may, for example, be higher than or equal to 10 rpm.

Next, the third nozzle 53 is moved from its retracted position to its supply position, and the substitution liquid is supplied from the third nozzle 53 to the central portion of the upper surface 91 of the substrate 9 (i.e., the central portion of the liquid membrane of the rinse liquid) (step S13). The substitution liquid may, for example, be IPA. The rotational speed of the substrate 9 during the supply of the substitution liquid may, for example, be in the range of 100 rpm to 300 rpm. The substitution liquid supplied to the central portion of the substrate 9 spreads radially outward from the central portion of the substrate 9 by centrifugal force caused by the rotation of the substrate 9, and applied to the entire upper surface 91 of the substrate 9. The rinse liquid on the substrate 9 (i.e., the rinse liquid that is in contact with the upper surface 91 of the substrate 9) is moved radially outward by the substitution liquid and removed from above the substrate 9. In the substrate processing apparatus 1, replacement processing for replacing the rinse liquid on the substrate 9 with the substitution liquid is performed by applying the substitution liquid to the substrate 9 for a predetermined time.

When the rinse liquid is removed from above the substrate 9 (i.e., when the rinse liquid on the substrate 9 is wholly replaced with the substitution liquid), the rotational speed of the substrate 9 is reduced. In this way, the liquid membrane of the substitution liquid is formed and maintained on the upper surface 91 of the substrate 9. The rotational speed of the substrate 9 may, for example, be 10 rpm. The liquid membrane of the substitution liquid covers the entire upper surface 91 of the substrate 9. When the liquid membrane of the substitution liquid is formed, the ejection of the substitution liquid from the third nozzle 53 is stopped, and the third nozzle 53 is retracted from its supply position to its retracted position. The rotational speed of the substrate 9 may be any rotational speed that does not cause drying of the upper surface 91 of the substrate 9, and may, for example, be higher than or equal 10 rpm.

Next, the fourth nozzle 54 is moved from its retracted position to its supply position, and the dry processing liquid is supplied from the fourth nozzle 54 to the central portion of the upper surface 91 of the substrate 9 (i.e., the central portion of the liquid membrane of the substitution liquid) (step S14). The dry processing liquid may, for example, be the first or second dry processing liquid described above. The rotational speed of the substrate 9 during the supply of the dry processing liquid may, for example, be in the range of 100 rpm to 300 rpm. The dry processing liquid supplied to the central portion of the substrate 9 spreads radially outward from the central portion of the substrate 9 by centrifugal force caused by the rotation of the substrate 9 and is applied to the entire upper surface 91 of the substrate 9. The substitution liquid on the substrate 9 (i.e., the substitution liquid that is in contact with the upper surface 91 of the substrate 9) is moved radially outward by the dry processing liquid and removed from above the substrate 9. In the substrate processing apparatus 1, the substitution liquid on the substrate 9 is wholly replaced with the dry processing liquid by applying the dry processing liquid to the substrate 9 for a predetermined time.

The dry processing liquid is heated in advance by the liquid heater 545 (see FIG. 4) before being ejected from the fourth nozzle 54 so that the temperature of the dry processing liquid while in contact with the upper surface 91 of the substrate 9 in step S14 becomes a predetermined contact temperature. If a temperature drop or the like of the dry processing liquid due to contact with the substrate 9 is taken into consideration, it is preferable that the temperature of the dry processing liquid ejected from the fourth nozzle 54 may, for example, be slightly higher than the contact temperature (however, lower than the boiling point of the dry processing liquid). When a temperature drop of the dry processing liquid does not occur so much due to contact with the substrate 9, the temperature of the dry processing liquid ejected from the fourth nozzle 54 may, for example, be approximately the same as the contact temperature. In other words, the dry processing liquid that is preheated to the contact temperature may be supplied to the upper surface 91 of the substrate 9.

The contact temperature is a temperature higher than or equal to the boiling point of the rinse liquid and lower than the boiling point of the dry processing liquid. This prevents vaporization of the dry processing liquid on the substrate 9 and, even if a component (e.g., moisture) of the rinse liquid is mixed into the dry processing liquid, allows the component of the rinse liquid to be vaporized and removed from the dry processing liquid. In the case where water is used as the rinse liquid, since the dry processing liquid has a temperature higher than or equal to the boiling point of the rinse liquid, it is possible to prevent moisture in the air from condensing and being mixed into the dry processing liquid. Preferably, a difference between the contact temperature and the boiling point of the dry processing liquid may be less than or equal to 65° C. In other words, it is preferable that the contact temperature is less than the boiling point of the dry processing liquid and higher than or equal to a temperature that is 65° C. lower than the boiling point of the dry processing liquid.

Even after the removal of the substitution liquid from above the substrate 9, the heated dry processing liquid continues to be supplied from the fourth nozzle 54 to the upper surface 91 of the substrate 9. This maintains the temperature of the dry processing liquid that is in contact with the upper surface 91 of the substrate 9 at the contact temperature described above. In step S14, the dry processing liquid having the contact temperature is in contact with the entire upper surface 91 of the substrate 9 for a predetermined contact time (preferably, 10 seconds or more). Accordingly, the molecules of the dry processing liquid are adsorbed on the upper surface 91 of the substrate 9 and on the surfaces of the aforementioned patterns on the upper surface 91 of the substrate 9.

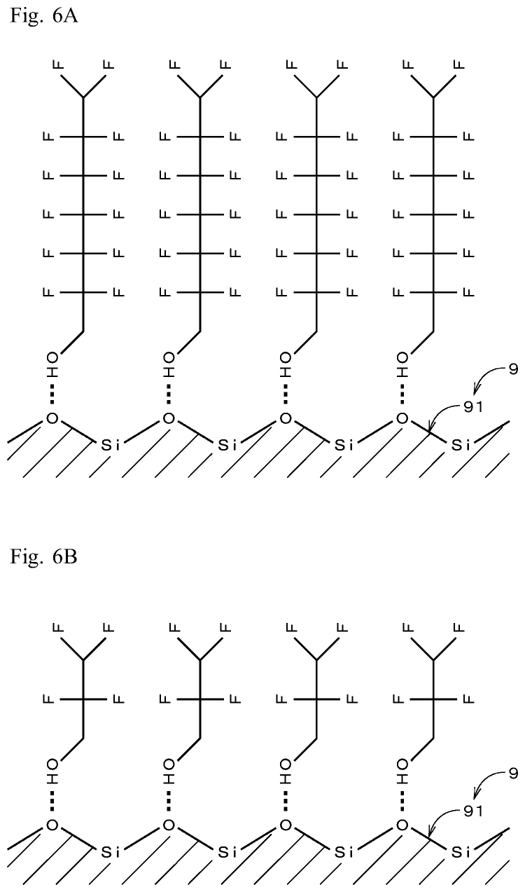

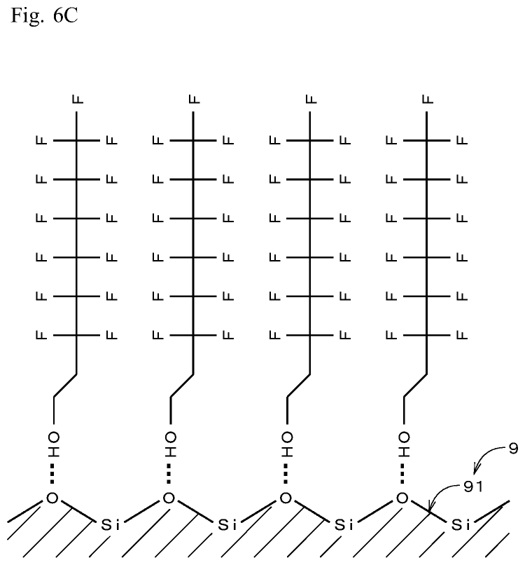

FIG. 6A schematically shows the molecules of the first dry processing liquid (i.e., 1H, 1H, 7H-Dodecafluoroheptanol) adsorbed on the upper surface 91 of the substrate 9. FIG. 6B schematically shows the molecules of the second dry processing liquid (i.e., 1H, 1H, 3H-Tetrafluoropropanol) adsorbed on the upper surface 91 of the substrate 9. FIG. 6C schematically shows the molecules of the third dry processing liquid (i.e., 2-(Perfluorohexyl)ethanol) adsorbed on the upper surface 91 of the substrate 9. FIGS. 6A to 6C show the skeletal structural formulas of the molecules of the first, second, and third dry processing liquids, respectively.

As shown in FIG. 6A, the molecules of the first dry processing liquid are adsorbed on the upper surface 91 of the substrate 9 as a result of the hydroxyl group (—OH) of the first dry processing liquid pulling oxygen atoms (O) on the upper surface 91 of the substrate 9 against each other. In this way, the upper surface 91 of the substrate 9 is covered with the molecules of the first dry processing liquid. To be more specific, the upper surface 91 of the substrate 9 is covered with —CF₂H existing at the terminals of the molecules of the first dry processing liquid. Similarly, in the case of the second dry processing liquid shown in FIG. 6B, the molecules of the second dry processing liquid are adsorbed on the upper surface 91 of the substrate 9, and the upper surface 91 of the substrate 9 is covered with —CF₂H existing at the terminals of the molecules of the second dry processing liquid. Approximately similarly, in the case of the third dry processing liquid shown in FIG. 6C, the molecules of the third dry processing liquid are adsorbed on the upper surface 91 of the substrate 9, and the upper surface 91 of the substrate 9 is covered with —CF₃ existing at the terminals of the molecules of the third dry processing liquid. Since FIGS. 6A to 6C are schematic diagrams, the direction and density of adsorption of the first, second, and third dry processing liquids on the substrate 9 are different from the actual direction and density of adsorption.

Similarly, in the case of the patterns on the upper surface 91 of the substrate 9, the molecules of the first dry processing liquid are adsorbed on the pattern surfaces, and the pattern surfaces are covered with —CF₂H existing at the terminals of the molecules of the first dry processing liquid. This reduces the surface free energy of the patterns and causes the angle of contact of the first dry processing liquid with the pattern surfaces to increase and approaches 90° as compared to the case where the first dry processing liquid is not adsorbed on the pattern surfaces. Similarly, in the case of the second dry processing liquid, the molecules of the second dry processing liquid are adsorbed on the pattern surfaces, and the pattern surfaces are covered with —CF₂H existing at the terminals of the molecules of the second dry processing liquid. This reduces the surface free energy of the patterns and causes the angle of contact of the second dry processing liquid with the pattern surfaces to increase and approach 90° as compared to the case where the second dry processing liquid is not adsorbed on the pattern surfaces. Approximately similarly, in the case of the third dry processing liquid, the molecules of the third dry processing liquid are adsorbed on the pattern surfaces, and the pattern surfaces are covered with —CF₃ existing at the terminals of the molecules of the third dry processing liquid. This reduces the surface free energy of the patterns and causes the angle of contact of the third dry processing liquid with the pattern surfaces to increase and approach 90° as compared to the case where the third dry processing liquid is not adsorbed on the pattern surfaces. In either of the cases where the first, second, and third dry processing liquids are adsorbed on the pattern surfaces, the surface free energy of the patterns with the dry processing liquid adsorbed thereon becomes lower than the surface free energy of silicon (Si) with no adsorption of the dry processing liquid.

On the pattern surfaces, as the fluorinated alkyl chains of the molecules of fluorine-containing alcohol become longer, the direction of adsorption of the molecules of the dry processing liquid on the pattern surfaces becomes closer to vertical, and the molecules of the dry processing liquid are more highly oriented on the pattern surfaces. The number of carbons (C) contained in the molecules of the first dry processing liquid shown in FIG. 6A is seven, and the number of carbons (C) contained in the molecules of the second dry processing liquid shown in FIG. 6B is three. In this way, the fluorinated alkyl chains of the molecules of the first dry processing liquid are longer than those of the molecules of the second dry processing liquid, and therefore the direction of adsorption of the molecules of the first dry processing liquid becomes more closer to vertical than the direction of adsorption of the molecules of the second dry processing liquid. Accordingly, the molecules of the first dry processing liquid are adsorbed with a higher density on the pattern surfaces than the molecules of the second dry processing liquid. As a result, in the case where the first dry processing liquid is used as the dry processing liquid, the amount of decrease in the surface free energy of the patterns increases and the contact angle with the pattern surfaces becomes closer to 90° as compared to the case where the second dry processing liquid is used as the dry processing liquid.

After the aforementioned contact time has elapsed since the dry processing liquid with the contact temperature has come in contact with the entire upper surface 91 of the substrate 9, the ejection of the dry processing liquid from the fourth nozzle 54 is stopped, and the fourth nozzle 54 is retracted from its supply position to its retracted position. Then, the top plate 61 is moved down from the first processing position to a position that is in closer proximity to the upper surface 91 of the substrate 9 (this position is hereinafter also referred to as the “second processing position”). In this way, the space between the upper surface 91 of the substrate 9 and the lower surface of the top plate 61 is substantially isolated from the surrounding space (i.e., space radially outward of the substrate 9).

Then, when the rotational speed of the substrate 9 is increased and the substrate 9 is rotated high speed by the substrate rotation mechanism 33, the dry processing liquid existing on the upper surface 91 of the substrate 9 is moved radially outward and removed from above the substrate 9 by centrifugal force. In the substrate processing apparatus 1, dry processing (so-called spin dry processing) on the substrate 9 is performed by continuing high-speed rotation of the substrate 9 by the substrate rotation mechanism 33 for a predetermined time (step S15). The substrate rotation mechanism 33 serves as a dry processor that dries the substrate 9 by removing the liquefied dry processing liquid from the upper surface 91 of the substrate 9.

In the dry processing on the substrate 9, the capillary action of pulling the patterns in the horizontal direction works while the liquid level of the dry processing liquid is lowered to a position between the patterns. The capillary action omax is expressed by Expression (1), where γ is the surface tension of the dry processing liquid, θ is the angle of contact between the dry processing liquid and the patterns, D is the distance between the patterns, H is the pattern height, and W is the pattern width.

ømax=(6γ·cosθ/D)·(H/W)² Expression (1)

In the substrate processing apparatus 1, the surface tension γ of the dry processing liquid is lower than the surface tension of the rinse liquid as described above. Thus, in the dry processing in step S15, the capillary action omax acting on the patterns can be reduced more than in the case where the rinse liquid (e.g., DIW) remaining on the substrate 9 after the rinsing processing is removed by spin dry processing or the like to dry the substrate 9 (hereinafter, also referred to as “rinse dry processing”). As a result, in the dry processing in step S15, pattern destruction is prevented more than in the rinse dry processing.

The substrate processing apparatus 1 also reduces the surface free energy of the patterns by causing fluorine-containing alcohol contained in the dry processing liquid to be adsorbed on the pattern surfaces. This allows the angle of contact 0 with the pattern surfaces to increase and approach 90° as compared to the case where the rinse liquid remaining on the substrate 9 after the rinsing processing is replaced with the substitution liquid (e.g., IPA) and then the substitution liquid is removed by spin dry processing or the like to dry the substrate 9 (hereinafter, also referred to as “replacement dry processing.” Accordingly, in the dry processing in step S15, the capillary action omax acting on the patterns can be reduced more than in the replacement dry processing. As a result, in the dry processing in step S15, pattern destruction is prevented more than in the replacement dry processing.

Note that conventional replacement dry processing may use, for example, IPA, methanol, or ethanol as the substitution liquid. Although IPA, methanol, and ethanol can be adsorbed on the pattern surfaces due to the presence of —OH, they do not contain fluorine and thus do not so much contribute to a decrease in the surface free energy of the patterns. Accordingly, there is a limit to preventing pattern destruction during dry processing.

Moreover, if hydrofluoroether (HFE), hydrofluorocarbon (HFC), or hydrofluoroolefin (HFO) is used instead of the dry processing liquid in step S14, the molecules of these liquids have no functional groups that are easily adsorbed on the pattern surfaces, such as —OH, at the terminals and are thus not substantially adsorbed on the pattern surfaces. Therefore, the surface free energy of the patterns does not decrease substantially. Accordingly, pattern destruction cannot be prevented favorably during dry processing.

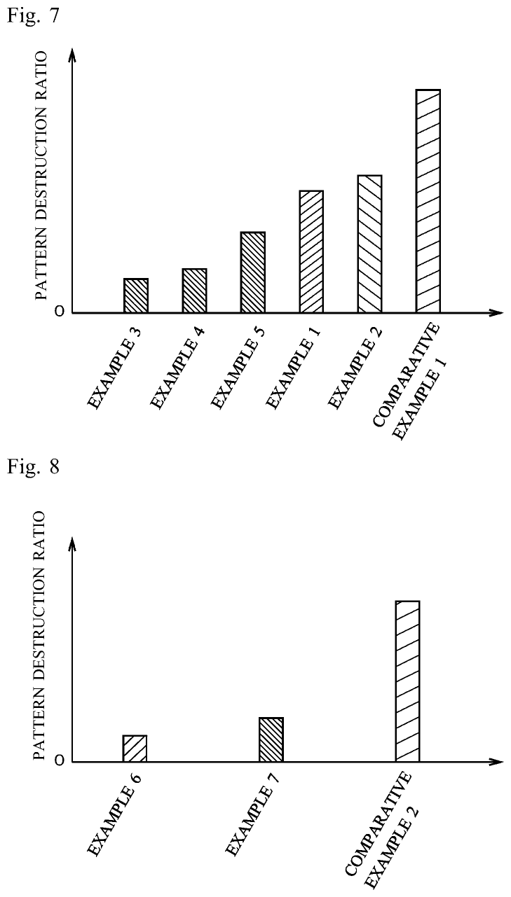

FIGS. 7 and 8 show experimental results of comparison between the destruction ratio of patterns on the substrate 9 after the above-described processing in steps S11 to S15 and the destruction ratio of patterns on the substrate 9 after the aforementioned replacement dry processing (i.e., processing for removing the substitution liquid on the substrate 9 by spin dry processing to dry the substrate 9 after steps S11 to S13 while omitting step S14). Each experiment in FIGS. 7 and 8 was conducted using test coupons having a surface with patterns formed thereon. FIG. 7 shows experimental results using a test coupon having a hydrophilic surface with an SiO₂ membrane formed thereon by natural oxidation. FIG. 8 shows experimental results using a test coupon having a hydrophobic surface that has undergone etch processing on an SiO₂ membrane.

The vertical axes In FIGS. 7 and 8 indicate the pattern destruction ratio on the surface of the test coupon. On the horizontal axes in FIGS. 7 and 8, “Example 1” and “Example 6” indicate experimental results corresponding to the above-described processing in steps S11 to S15 in the case of using the first dry processing liquid as the dry processing liquid. “Example 2” on the horizontal axis indicates an experimental result corresponding to the above-described processing in steps S11 to S15 in the case of using the second dry processing liquid as the dry processing liquid. “Example 3,” “Example 4,” “Example 5,” and Example 7″ on the horizontal axes indicate experimental results corresponding to the above-described processing in steps S11 to S15 in the case of using the third dry processing liquid as the dry processing liquid. “Comparative Example 1” on the horizontal axis indicates an experimental result corresponding to the replacement dry processing in the case of using IPA as the substitution liquid (i.e., processing that omits step S14). “Comparative Example 2” on the horizontal axis indicates an experimental result corresponding to the above-described processing in steps S11 to S15 in the case of using a kind of HFE, namely HFE-7100 (represented by a rational formula of C₄F₉OCH₃; methoxy-nonafluorobutane), instead of the dry processing liquid in the processing in step S14.

The test coupons were approximately rectangular flat-plate members measuring 20 mm per side. The aspect ratio of the patterns formed on the surface of each test coupon (AR: the ratio between the bottom and height of the patterns) was 20.

In Example 1 in FIG. 7, the test coupon was immersed in the first dry processing liquid having the contact temperature in a beaker for one minute and then taken out of the beaker for air seasoning. The contact temperature was a temperature that was 10° C. lower than the boiling point of the first dry processing liquid. Thereafter, the pattern destruction ratio on the test coupon was obtained. The pattern destruction ratio on the substrate 9 having a hydrophilic surface in Example 1 was approximately 47%. The pattern destruction ratio was obtained through image analysis of the test coupon. The same method of obtaining the pattern destruction ratio was also used in Examples 2 to 7 and Comparative Examples 1 and 2.

In connection with Example 1, the pattern destruction ratio was obtained by varying the contact temperature of the first dry processing liquid within a range of temperatures lower than the boiling point of the first dry processing liquid. This result showed that the destruction ratio increased with an increase in the difference between the contact temperature and the boiling point. Moreover, in connection with Example 1, the contact angle of the first dry processing liquid with the test coupon was obtained by varying the aforementioned contact time. This result showed that the contact angle increased as the contact time increased within a range shorter than or equal to 15 minutes, but the contact angle does not change so much when the contact time became 15 minutes or more.

Example 2 in FIG. 7 was similar to Example 1, except that the first dry processing liquid was changed to the second dry processing liquid and the contact temperature was set to a temperature that was 10° C. lower than the boiling point of the second dry processing liquid. The pattern destruction ratio on the substrate 9 having a hydrophilic surface in Example 2 was approximately 53%.

Example 3 in FIG. 7 was similar to Example 1, except that the first dry processing liquid was changed to the third dry processing liquid and the contact temperature was set to a temperature that was 40° C. lower than the boiling point of the third dry processing liquid. The pattern destruction ratio on the substrate 9 having a hydrophilic surface in Example 3 was approximately 13%.

Example 4 in FIG. 7 was similar to Example 1, except that the first dry processing liquid was changed to the third dry processing liquid and the contact temperature was set to a temperature that was 65° C. lower than the boiling point of the third dry processing liquid. The pattern destruction ratio on the substrate 9 having a hydrophilic surface in Example 4 was approximately 17%.

Example 5 in FIG. 7 was similar to Example 1, except that the first dry processing liquid was changed to the third dry processing liquid and the contact temperature was set to a temperature that was 90° C. lower than the boiling point of the third dry processing liquid. The pattern destruction ratio on the substrate 9 having a hydrophilic surface in Example 5 was approximately 31%.

Comparative Example 1 in FIG. 7 was similar to Example 1, except that the first dry processing liquid was changed to IPA and the contact temperature was set to a temperature that was 10° C. lower than the boiling point of IPA. The pattern destruction ratio on the substrate 9 having a hydrophilic surface in Comparative Example 1 was approximately 86%.

As shown in FIG. 7, pattern destruction on the substrate 9 having a hydrophilic surface can be prevented more by performing the above-described processing in steps S11 to S15 (Examples 1 to 5) than by performing the replacement dry processing omitting step S14 (Comparative Example 1). That is, even if the substrate 9 has a hydrophilic surface that exhibits a higher pattern destruction ratio than a hydrophobic surface in conventional dry processing (Comparative Example 1), pattern destruction can be prevented by performing the processing in steps S11 to S15 according to the invention of the present application (Examples 1 to 5).

A comparison of Example 1 and Example 2 shows that pattern destruction can be prevented more by using the first dry processing liquid whose molecular formula contains 7 carbons (Example 1), out of the first and second dry processing liquids having —CF₂H at the terminal, than by using the second dry processing liquid whose molecular formula contains 3 carbons (Example 2). A comparison of Example 1 and Examples 3 to 5 shows that pattern destruction can be prevented more by using the third dry processing liquid having —CF₃ at the terminal (Examples 3 to 5) than by using the first dry processing liquid having —CF₂H at the terminal (Example 1). A comparison of Example 5 and Examples 3 and 4 shows that pattern destruction can be prevented more by setting the difference between the contact temperature and the boiling point of the third dry processing liquid to be less than or equal to 65° C. (Examples 3 and 4) than by setting the difference between the contact temperature and the boiling point of the third dry processing liquid to be larger than 65° C. (Example 5 with a temperature difference of) 90° C.

In Example 6 in FIG. 8, using a beaker, the test coupon was immersed in a dilute hydrofluoric acid (with a concentration of approximately 1% by volume) for one minutes, then immersed in DIW for one minute, further immersed in IPA for three minutes, and then immersed in the first dry processing liquid having an ambient temperature. Then, the temperature of the first dry processing liquid was increased to the contact temperature that was 10° C. lower than the boiling point of the first dry processing liquid, and the test coupon was maintained therein for one minute. Thereafter, the test coupon was taken out of the beaker for air seasoning, and the pattern destruction ratio was obtained. The pattern destruction ratio on the substrate 9 having a hydrophobic surface in Example 6 was approximately 10%.

Example 7 in FIG. 8 was similar to Example 6, except that the first dry processing liquid was changed to the third dry processing liquid and the contact temperature was set to a temperature that was 40° C. lower than the boiling point of the third dry processing liquid. The pattern destruction ratio on the substrate 9 having a hydrophilic surface in Example 7 was approximately 17%.

Comparative Example 2 in FIG. 8 was similar to Example 6, except that the first dry processing liquid was changed to HFE-7100 and the contact temperature was set to a temperature that was 10° C. lower than the boiling point of HFE-7100. The pattern destruction ratio on the substrate 9 having a hydrophobic surface in Comparative Example 2 was approximately 62%.

As shown in FIG. 8, pattern destruction on the substrate 9 having a hydrophobic surface can be prevented more by using the dry processing 1 liquid to perform the above-described processing in steps S11 to S15 (Example 6 to 7) than by using HFE to perform steps S11 to S15 (Comparative Example 2). A comparison of Example 6 and Example 7 shows that pattern destruction can be prevented more by using the first dry processing liquid having —CF₂H at the terminal (Example 6) than by using the third dry processing liquid having —CF₃ at the terminal (Example 7).

When step S15 described above (dry processing on the substrate 9) has ended, the substrate heater 7 heats the substrate 9 to remove the molecules of the dry processing liquid adsorbed on the surface of the substrate 9 (i.e., the pattern surfaces or the like on the substrate 9) (step S16). In the processing for removing the adsorbed molecules in step S16, the temperature of the substrate 9 (hereinafter, also referred to as a “molecular removal temperature”) is set to a temperature higher than the boiling point of the dry processing liquid described above. The molecules of the dry processing liquid removed from above the substrate 9 in step S16 are not the liquefied dry processing liquid, but a slight amount of adsorbed molecules remaining on the substrate 9 even after the removal of the liquefied dry processing liquid from above the substrate 9 by the dry processing in step S15. When step S16 has ended, the substrate 9 is transported out of the substrate processing apparatus 1.

In the above-described example, the processing for removing adsorbed molecules in step S16 is performed on the substrate 9 held by the substrate holder 31 within the same chamber 11 where steps S11 to S15 are performed, but the present invention is not limited to this example. For example, one chamber 11 may include a hot plate separately from the substrate holder 31, and the processing for removing adsorbed molecules may be performed by placing and heating the substrate 9 on this hot plate after completion of step S15. As another alternative, after completion of step S15, the substrate 9 may be transferred to a different processing unit 108 (see FIG. 1) from the processing unit 108 serving as the substrate processing apparatus 1, and the different processing unit 108 may perform the processing for removing adsorbed molecules on the substrate 9 through ashing using plasma, UV, excimer, or the like.

In the above-described example, the processing for replacing the rinse liquid with the substitution liquid in step S13 is performed between the rinsing processing in step S12 and the supply of the dry processing liquid in step S14, but step S13 may be omitted if the rinse liquid can be removed favorably from above the substrate 9 by directly supplying the dry processing liquid to the liquid membrane of the rinse liquid on the substrate 9. For example, step S13 may be omitted if the rinse liquid has somewhat high affinity with the dry processing liquid. As another alternative, for example, step S13 may also be omitted in cases such as where the dry processing liquid has somewhat greater specific gravity than the rinse liquid and the dry processing liquid is favorably settled down at the bottom of the liquid membrane of the rinse liquid by supplying the dry processing liquid at a low flow rate to the liquid membrane.

In the above-described example, the dry processing liquid having the contact temperature described above comes in contact with the substrate 9 as a result of supplying the preheated dry processing liquid to the substrate 9 in step S14, but the present invention is not limited to this example. For example, the temperature of the dry processing liquid may be increased to and maintained at the contact temperature by supplying the preheated dry processing liquid onto the substrate 9 and further heating the dry processing liquid on the substrate 9 by the substrate heater 7. The heating of the dry processing liquid on the substrate 9 may be implemented by a configuration other than the substrate heater 7. For example, the dry processing liquid on the substrate 9 may be heated by supplying a heated inert gas from the lower nozzle 56 to the lower surface 92 of the substrate 9.

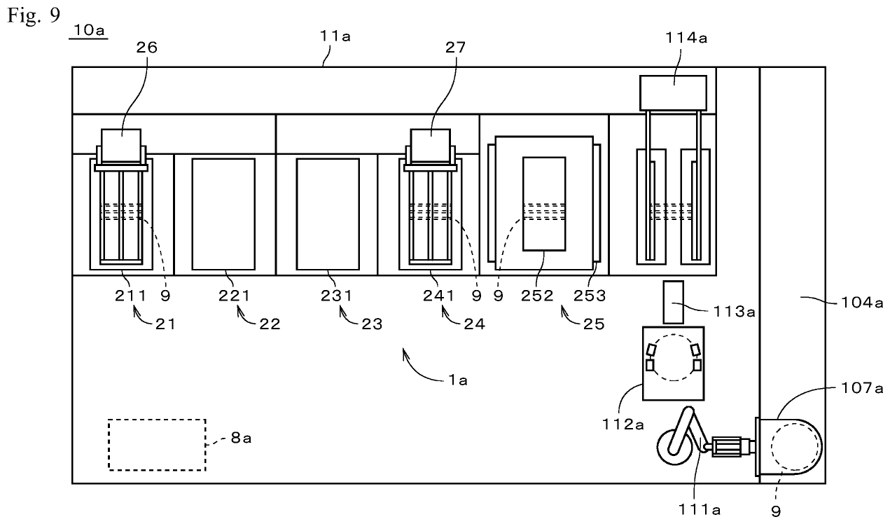

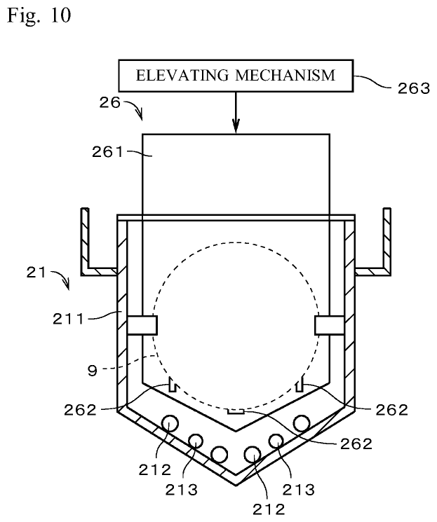

Next description is given of a substrate processing system 10a according to a second embodiment of the present invention. FIG. 9 is a diagrammatic plan view showing a layout of the substrate processing system 10a. The substrate processing system 10a is a batch type apparatus that performs liquid processing collectively on a plurality of substrates 9.

The substrate processing system 10a includes a carrier holder 104a, a substrate transfer robot 111a, an attitude conversion mechanism 112a, a pusher 113a, a substrate transport mechanism 114a, a substrate processing apparatus 1a serving as a processing unit, and a controller 8a. The controller 8a has a structure approximately similar to that of the controller 8 described above, and controls constituent elements such as the substrate transfer robot 111a, the attitude conversion mechanism 112a, the pusher 113a, the substrate transport mechanism 114a, and the substrate processing apparatus 1a. The constituent elements including the substrate transfer robot 111a, the attitude conversion mechanism 112a, the pusher 113a, the substrate transport mechanism 114a, and the substrate processing apparatus 1a are housed inside a chamber 11a.

The carrier holder 104a holds a carrier 107a (e.g., FOUP). The substrate transfer robot 111a transports a plurality of (e.g., 25) substrates 9 in a horizontal position out of the carrier 107a held by the carrier holder 104a and transfers the substrates 9 to the attitude conversion mechanism 112a. The substrates 9 are aligned at approximately regular intervals in the thickness direction. The attitude conversion mechanism 112a is a mechanism for converting the orientation of the substrates 9 between a horizontal position and a standing position (i.e., a position in which the main surfaces of the substrates 9 become approximately parallel to one another in the up-down direction). For example, the attitude conversion mechanism 112a may include a holder that holds a plurality of substrates 9 and a rotation mechanism that rotates the holder by 90°. The rotation mechanism may have various structures and may, for example, be an electric rotary motor.

The attitude conversion mechanism 112a converts the horizontal position of the substrates 9 received from the substrate transfer robot 111a to a standing position. The pusher 113a receives the substrates 9 in a standing position from the attitude conversion mechanism 112a and transfers the substrates 9 to the substrate transport mechanism 114a. The substrate transport mechanism 114a includes a holder that holds a plurality of substrates 9 in a standing position and a movement mechanism that moves the holder in the horizontal direction. The movement mechanism may include, for example, an electric linear motor, an air cylinder, or a ball screw and an electric rotary motor. The substrate transport mechanism 114a transports the substrates 9 in a standing position into the substrate processing apparatus 1a, which serves as a processing unit. Processing to be performed on the substrates 9 by the substrate processing apparatus 1a will be described later.

The substrates 9 processed by the substrate processing apparatus 1a is transported out of the substrate processing apparatus 1a by the substrate transport mechanism 114a and transferred to the attitude conversion mechanism 112a by the pusher 113a. The attitude conversion mechanism 112a converts the standing position of the substrates 9 to a horizontal position and transfers the substrates 9 to the substrate transfer robot 111a. The substrate transfer robot 111a transports the substrates 9 in a horizontal position into the carrier 107a.

The substrate processing apparatus 1a includes a first processing unit 21, a second processing unit 22, a third processing unit 23, a fourth processing unit 24, a fifth processing unit 25, and lifters 26 and 27. The first processing unit 21 includes a processing bath 211 for storing the aforementioned chemical solution. The second processing unit 22 includes a processing bath 221 for storing the aforementioned rinse liquid. The third processing unit 23 includes a processing bath 231 for storing the aforementioned substitution liquid. The fourth processing unit 24 includes a processing bath 241 for storing the aforementioned dry processing liquid. AS in the case of the substrate processing apparatus 1, the dry processing liquid contains fluorine-containing alcohol. The dry processing liquid may, for example, contain fluorine-containing alcohol having —CF₂H or —CF; at the terminal. The surface tension of the dry processing liquid is lower than the surface tension of the rinse liquid, and the boiling point of the dry processing liquid is higher than the boiling point of the rinse liquid.

Each of the lifters 26 and 27 serves as a substrate holder that receives and holds a plurality of substrates 9 in a standing position from the substrate transport mechanism 114a. The lifter 26 moves between the first processing unit 21 and the second processing unit 22 while holding the substrates 9 in a standing position. The lifter 27 moves between the third processing unit 23 and the fourth processing unit 24 while holding the substrates 9 in a standing position. Each of the lifters 26 and 27 moves the holding substrates 9 in the up-down direction. The movement of the lifters 26 and 27 and the rise and fall of the substrates 9 may be implemented by, for example, an electric linear motor, an air cylinder, or a ball screw and an electric rotary motor.

FIG. 10 is a side view showing the first processing unit 21 and the lifter 26. FIG. 10 shows the processing bath 211 in cross section and also shows a substrate 9 held by the lifter 26. The first processing unit 21 includes the processing bath 211 having a longitudinal section of an approximately pentagonal shape, processing-liquid supply pipes 212, and gas supply pipes 213. The second, third, and fourth processing units 22, 23, and 24 have approximately similar structures to the structure of the first processing unit 21.

The lifter 26 includes an approximately flat plate-like main body 261 that extends in approximately parallel with the up-down direction, and three holding rods 262 that extend in the horizontal direction from one main surface of the main body 261. In the lifter 26, the lower edges of the substrates 9 aligned in a standing position in a direction perpendicular to the plane of the drawing are held by the three holding rods 262. The lifter 26 further includes an elevating mechanism 263 that moves the main body 261 in the up-down direction. The elevating mechanism 263 may include, for example, an electric linear motor, an air cylinder, or a ball screw and an electric rotary motor that are connected to the main body 261.

In the first processing unit 21, the chemical solution supplied from the processing-liquid supply pipes 212 is stored in the processing bath 211. Then, the substrates 9 held by the lifter 26 are immersed in the chemical solution stored in the processing bath 211 while the chemical solution continues to be supplied from the processing-liquid supply pipes 212. Following this, an inert gas such as a nitrogen gas is supplied from the gas supply pipes 213, so that air bubbles of the inert gas come up in the processing bath 211. Accordingly, the chemical solution is stirred in the vicinity of the surfaces of the substrates 9 is stirred, and a new chemical solution continues to be supplied to the surfaces of the substrates 9. As a result, the speed of the chemical processing on the substrate 9 increases.

The fifth processing unit 25 shown in FIG. 9 includes a substrate holder 252 that holds a plurality of substrates 9 in a standing position and performs processing (i.e., dry processing) for removing a liquid from the surfaces of the substrates 9 held by the substrate holder 252. For example, the fifth processing unit 25 may perform dry processing by shaking off the liquid from the surfaces of the substrates 9 by centrifugal force. Alternatively, the fifth processing unit 25 may perform dry processing by supplying an organic solvent (e.g., IPA) to the substrates 9. The dry processing by the fifth processing unit 25 may be implemented by other various methods. The fifth processing unit 25 further includes a substrate heater 253 that heats the substrates 9 held by the substrate holder 252. For example, the substrate heater 253 may heat the substrates 9 by irradiating the substrates 9 with light. Note that the substrate heater 253 may use a method other than photoirradiation to heat the substrates 9.

Next description is given of a procedure of the processing performed on the substrates 9 by the substrate processing apparatus 1a. In the substrate processing apparatus 1a, firstly, the lifter 26 receives and holds a plurality of substrates 9 in a standing position from the substrate transport mechanism 114a. The lifter 26 then lowers the substrates 9 and immerses the substrates 9 in the chemical solution stored in the processing bath 211 of the first processing unit 21. In this way, the chemical solution is supplied to the entire surface (i.e., both main and side surfaces) of each substrate 9 (step S11 in FIG. 5). In the substrate processing apparatus 1a, the first processing unit 21 serving as the chemical solution supplier performs chemical processing on the substrates 9 by immersing the substrates 9 in the chemical solution for a predetermined time.

When the chemical processing on the substrates 9 has ended, the lifter 26 lifts the substrates 9 up from the processing bath 211 of the first processing unit 21 and transfers the substrates 9 to the second processing unit 22. Then, the lifter 26 lowers the substrates 9 and immerses the substrates 9 in the rinse liquid stored in the processing bath 221 of the second processing unit 22. In this way, the rinse liquid is supplied to the entire surface of each substrate 9 (step S12). In the substrate processing apparatus 1a, the second processing unit 22 serving as the rinse liquid supplier performs rinsing processing on the substrates 9 by immersing the substrates 9 in the rinse liquid for a predetermined time.

When the rinsing processing on the substrates 9 has ended, the lifter 26 lifts the substrates 9 up from the processing bath 221 of the second processing unit 22 and transfers the substrates 9 to the substrate transport mechanism 114a. The substrate transport mechanism 114a transfers the substrates 9 to the lifter 27. The lifter 27 lowers the substrates 9 in a standing position and immerses the substrates 9 in the substitution liquid stored in the processing bath 231 of the third processing unit 23. In this way, the substitution liquid is supplied to the entire surface of each substrate 9 (step S13). In the substrate processing apparatus 1a, the third processing unit 23 serving as the substitution-liquid supplier performs replacement processing for replacing the rinse liquid on the substrate 9 with the substitution liquid (i.e., replacement processing for replacing the rinse liquid that is in contact with the surfaces of the substrates 9 with the substitution liquid) by immersing the substrates 9 in the substitution liquid for a predetermined time.

When the above replacement processing has ended, the lifter 27 lifts the substrates 9 up from the processing bath 231 of the third processing unit 23 and transfers the substrates 9 to the fourth processing unit 24. Then, the lifter 27 lowers the substrates 9 and immerses the substrates 9 in the dry processing liquid stored in the processing bath 241 of the fourth processing unit 24. In this way, the dry processing liquid is supplied to the entire surface of each substrate 9 (step S14). In other words, the substitution liquid that is in contact with the surfaces of the substrates 9 is replaced with the dry processing liquid.

The dry processing liquid in the processing bath 241 is preheated in the same manner as described above so that the temperature of the dry processing liquid when in contact with the surfaces of the substrates 9 becomes a predetermined contact temperature. The contact temperature is a temperature higher than or equal to the boiling point of the rinse liquid and lower than the boiling point of the dry processing liquid. For example, a difference between the contact temperature and the boiling point of the dry processing liquid may preferably be less than or equal to 65° C.

In the substrate processing apparatus 1a, the fourth processing unit 24 serving as the dry processing liquid supplier immerses the substrates 9 in the dry processing liquid having the contact temperature for a predetermined contact time (preferably, 10 seconds or more), so that the molecules of the dry processing liquid are adsorbed on the surfaces of the substrates 9 and on the aforementioned pattern surfaces on the surfaces of the substrates 9. Note that the fourth processing unit 24 may include a heater (e.g., a heating-wire heater) not shown that heats the processing bath 241 and increases the temperature of the dry processing liquid to the contact temperature by heating the dry processing liquid supplied to the processing bath 241 (i.e., the dry processing liquid that have come in contact with the surfaces of the substrates 9). In this case, the temperature of the dry processing liquid to be supplied to the processing bath 241 may be an ordinary temperature, or may be a temperature between an ordinary temperature and the contact temperature.

After the aforementioned contact time has elapsed since the contact of the dry processing liquid having the contact temperature with the entire surfaces of the substrates 9, the lifter 27 lifts the substrates 9 up from the processing bath 241 of the fourth processing unit 24 and transfers the substrates 9 to the substrate transport mechanism 114a. The substrate transport mechanism 114a transports the substrates 9 to the fifth processing unit 25 and transfers the substrates 9 to the substrate holder 252 of the fifth processing unit 25. The fifth processing unit 25 serving as the dry processing unit performs dry processing on the substrates 9 in a standing position (i.e., removal of the liquefied dry processing liquid from the surfaces of the substrates 9) (step S15). By using the aforementioned dry processing liquid, the substrate processing apparatus 1a prevents pattern destruction during the dry processing in the same manner as described above.

When step S15 (dry processing on the substrates 9) has ended, the substrate heater 253 heats the substrates 9 to remove the molecules of the dry processing liquid adsorbed on the substrates 9 (step S16). In the processing for removing adsorbed molecules in step S16, the temperature of the substrates 9 (i.e., molecular removal temperature) is set to a temperature higher than the aforementioned contact temperature and the boiling point of the dry processing liquid. The molecules of the dry processing liquid removed from above the substrates 9 in step S16 are not the liquefied dry processing liquid, but a slight amount of adsorbed molecules remaining on the substrates 9 even after the removal of the liquefied dry processing liquid from above the substrates 9 by the dry processing in step S15. When step S16 has ended, the substrate transport mechanism 114a takes the substrates 9 out of the fifth processing unit 25 and transports the substrates 9 out of the substrate processing apparatus 1a serving as the processing unit.

In the above-described example, the processing for removing adsorbed molecules in step S16 is performed in the same chamber 11a where steps S11 to S15 are performed, but the present invention is not limited to this example. For example, the substrates 9 that have undergone step S15 may be transported out of the chamber 11a and subjected to processing for removing adsorbed molecules on the substrates 9 by ashing using plasma or the like performed in a different apparatus.

Like the substrate processing apparatus 1, the substrate processing apparatus 1a may also omit step S13.

As described thus far, the substrate processing method for processing substrates 9 includes the step of supplying a chemical solution to the surfaces of the substrates 9 (step S11), the step of supplying a rinse liquid to the surfaces of the substrates 9 after step S11 (step S12), the step of bringing a heated dry processing liquid into contact with the surfaces of the substrates 9 after step S12 (step S14), and the step of drying the substrates 9 by removing the dry processing liquid from the surfaces of the substrates 9 after step S14 (step S15). The surface tension of the dry processing liquid is lower than the surface tension of the rinse liquid. The boiling point of the dry processing liquid is higher than the boiling point of the rinse liquid. The temperature of the dry processing liquid that comes in contact with the surfaces of the substrates 9 in step S14 is a predetermined contact temperature higher than or equal to the boiling point of the rinse liquid and lower than the boiling point of the dry processing liquid. This prevents pattern destruction during the dry processing in step S15. Besides, the amount of time from when the supply of the dry processing liquid is started to when the dry processing liquid having the contact temperature comes in contact with the substrates 9 can be reduced more than in the case where the dry processing liquid having an ordinary temperature is supplied to the substrates 9 and then heated to the contact temperature. As a result, it is possible to shorten the time required for the processing on the substrates 9.

As described above, the dry processing liquid may preferably contain fluorine-containing alcohol. In this case, as described above, —OH of the dry processing liquid is bonded to, for example, oxygen atoms (O) on the pattern surfaces in step S14, and the molecules of the dry processing liquid are adsorbed on the pattern surfaces. Thus, the pattern surfaces are coated with the molecules of the dry processing liquid. Accordingly, as compared to the case where the dry processing liquid is not adsorbed on the pattern surfaces, the surface free energy of the patterns decreases and the contact angle of the dry processing liquid with the pattern surfaces increases and approaches 90°. As a result, the capillary action acting between the patterns is reduced, and pattern destruction can be further prevented during the dry processing in step S15.

The aforementioned fluorine-containing alcohol may preferably have —CF₂H at the terminal. In this case, the pattern surfaces are coated with —CF₂H existing at the terminals of the molecules of the dry processing liquid. This difluoromethyl group —CF₂H at the terminals of the molecules has a considerable effect in reducing the surface free energy. Therefore, pattern destruction can be further prevented during the dry processing in step S15.

The fluorine-containing alcohol may also preferably contain —CF₃ at the terminal. In this case, the pattern surfaces are covered with —CF₃ existing at the terminals of the molecules of the dry processing liquid. Approximately similar in the case of —CF₂H, —CF₃ at the terminals of the molecules have a considerable effect in reducing the surface free energy. Therefore, pattern destruction can be further prevented during the dry processing in step S15.

As described above, the number of carbons (C) contained in the molecular formula of the fluorine-containing alcohol may preferably be 4 or higher. As indicated by the experimental results shown in FIG. 7, if the number of carbons (C) is 4 or more (Example 1), pattern destruction can be reduced yet more than in the case where the number of carbons (C) is less than 4 (Example 2).

Preferably, the substrate processing method described above may further include the step of removing the molecules of the dry processing liquid adsorbed on the surfaces of the substrates 9 by heating the substrates 9 after step S15 (step S16). By removing unnecessary adsorbates on the surfaces of the substrates 9 in this way, it is possible to improve cleanability of the substrates 9.

As described above, step S16 (processing for removing adsorbed molecules) and step S15 (dry processing) may preferably be performed in the same chamber 11 or 11a. In this case, it is possible to shorten the time required for the processing on substrates 9 in steps S11 to S16.

Preferably, the substrate processing method described above may further include the step of supplying the substitution liquid to the surfaces of the substrates 9 and replacing the rinse liquid that is in contact with the surfaces of the substrates 9 with the substitution liquid (step S13) between step S12 (supply of the rinse liquid) and step S14 (supply of the dry processing liquid). In this case, the substitution liquid that is in contact with the surfaces of the substrates 9 is replaced with the dry processing liquid in step S14. This avoids direct contact of the rinse liquid on the substrates 9 with the dry processing liquid. Thus, even if the rinse liquid has relatively low affinity with the dry processing liquid, it is possible to smoothly change the processing liquid that comes in contact with the surfaces of the substrates 9 from the rinse liquid to the dry processing liquid while preventing the occurrence of hazards such as liquid splash due to the direct contact with the rinse liquid and the dry processing liquid.

As described above, the dry processing liquid preheated to the contact temperature may preferably be supplied to the surfaces of the substrates 9 in step S14. In this case, it is possible to further shorten the time required for the processing on the substrates 9.

As described above, the temperature of the dry processing liquid may also be increased to the contact temperature by heating the dry processing liquid that has come in contact with the surfaces of the substrates 9 in step S14. This improves in-plane uniformity of the temperature of the dry processing liquid on the surfaces of the substrates 9. In other words, it is possible to reduce a temperature difference caused by a different in position on the surfaces of the substrates 9. As a result, it is also possible to improve in-plane uniformity of adsorption of the molecules of the dry processing liquid on the pattern surfaces on the substrates 9. Accordingly, pattern destruction can be prevented approximately evenly on the entire surfaces of the substrates 9.

As described above, the difference between the contact temperature and the boiling point of the dry processing liquid may preferably be less than or equal to 65° C. (e.g., Examples 3 and 4 in FIG. 7). This allows efficient adsorption of the molecules of the dry processing liquid on the patterns. As a result, pattern destruction can be reduced more than in the case where the difference between the contact temperature and the boiling point of the dry processing liquid is larger than 65° C. (Example 5).

As described above, the contact time of the dry processing liquid having the contact temperature with the surfaces of the substrates 9 may preferably be 10 seconds or more in step S14. This allows satisfactory adsorption of the molecules of the dry processing liquid on the pattern surfaces on the substrates 9. As a result, pattern destruction can be further prevented during the dry processing in step S15.

The substrate processing apparatuses 1 and 1a described above include a chemical solution supplier that supplies a chemical solution to surfaces of substrates 9 (the first nozzle 51 or the first processing unit 21 in the above-described example), a rinse liquid supplier that supplies a rinse liquid to the surfaces of the substrates 9 (the second nozzle 52 or the second processing unit 22 in the above-described example), a dry processing liquid supplier that supplies a heated dry processing liquid to the surfaces of the substrates 9 (the fourth nozzle 54 or the fourth processing unit 24 in the above-described example), and the dry processing unit that dries the substrates 9 by removing the dry processing liquid from the surfaces of the substrates 9 (the substrate rotation mechanism 33 or the fifth processing unit 25 in the above-described example). The surface tension of the dry processing liquid is lower than the surface tension of the rinse liquid. The boiling point of the dry processing liquid is higher than the boiling point of the rinse liquid. The temperature of the dry processing liquid that comes in contact with the surfaces of the substrates 9 is a predetermined contact temperature higher than or equal to the boiling point of the rinse liquid and lower than the boiling point of the dry processing liquid. Thus, it is possible to reduce pattern destruction during dry processing as described above.

As described above, the dry processing liquid may preferably contain fluorine-containing alcohol. In this case, as described above, it is possible to further prevent pattern destruction during the dry processing in step S15 in the same manner as described above.

The dry processing liquid is in particular suitable for substrate processing that requires to prevent pattern destruction during dry processing.

The substrate processing apparatuses 1 and 1a, the substrate processing method, and the dry processing liquid described above may be modified in various ways.

For example, the dry processing liquid is not limited to the first dry processing liquid and the second dry processing liquid described above, and may be a liquid that contains a different type of fluorine-containing alcohol having —CF₂H at the terminal. Alternatively, the dry processing liquid may be a liquid that contains various types of fluorine-containing alcohol having —CF₃ at the terminal as described above. As another alternative, the dry processing liquid may be a liquid that contains various types of fluorine-containing alcohol having a structure other than —CF₂H and —CF₃ at the terminal. The number of carbons (C) contained in the molecular formula of the fluorine-containing alcohol may be three or less, or may be eight or more. Note that the dry processing liquid may be a liquid that does not contain fluorine-containing alcohol.

In step S14, the contact time of the dry processing liquid having the contact temperature with the surface of the substrate 9 may be less than 10 seconds. The difference between the contact temperature and the boiling point of the dry processing liquid may be larger than 65° C.

In the substrate processing apparatus 1, the removal of the dry processing liquid from above the substrate 9 in the dry processing in step S15 does not necessarily have to be implemented by only the rotation of the substrate 9, and may be implemented by any other various methods. For example, part of the dry processing liquid on the substrate 9 that is in contact with the substrate 9 may be vaporized to form a gas space by heating the substrate 9 to a temperature higher than or equal to the boiling point of the dry processing liquid, and gas such as a nitrogen gas may be jetted to the central portion of the liquid membrane of the dry processing liquid supported on the gas space so as to form a hole in the central portion of the liquid membrane. Then, the liquefied dry processing liquid may be removed from above the substrate 9 by enlarging that hole radially outward by further jetting of the nitrogen gas and the rotation of the substrate 9.

After step S15 has ended, the processing for removing adsorbed molecules in step S16 may be omitted in cases such as where the molecules of the dry processing liquid adsorbed on the pattern surfaces do not substantially have adverse influences on the quality of the substrate 9.

Steps S11 to S16 described above may be performed by any other apparatus having a structure different from the structures of the substrate processing apparatuses 1 and 1a. The dry processing liquid described above may also be used in any other apparatus having a structure different from the structures of the substrate processing apparatuses 1 and 1a.

The substrate processing apparatuses 1 and 1a described above may be used for processing on substances other than semiconductor substrates, such as glass substrates for use in flat panel displays such as liquid crystal displays or organic electroluminescence (EL) displays, or glass substrates for use in other displays. The substrate processing apparatus 1 described above may be used for processing on other substrates such as optical disk substrates, magnetic disk substrates, magneto-optical disk substrates, photomask substrates, ceramic substrates, or solar cell substrates.

The configurations of the above-described preferred embodiment and variations may be appropriately combined as long as there are no mutual inconsistencies.

While the invention has been shown and described in detail, the foregoing description is in all aspects illustrative and not restrictive. It is therefore understood that numerous modifications and variations can be devised without departing from the scope of the invention.

### REFERENCE SIGNS LIST

1, 1a substrate processing apparatus
9 substrate
11, 11a chamber
21 first processing unit
22 second processing unit
23 third processing unit
24 fourth processing unit
25 fifth processing unit
33 substrate rotation mechanism
51 first nozzle
52 second nozzle
53 third nozzle
54 fourth nozzle
91 upper surface (of a substrate)
92 lower surface (of a substrate)
J1 central axis
S11 to S16 step

1. A substrate processing method for processing a substrate, comprising:
a) supplying a chemical solution to a surface of a substrate;
b) supplying a rinse liquid to said surface of said substrate after said operation a);
c) bringing a heated dry processing liquid into contact with said surface of said substrate after said operation b); and
d) drying said substrate by removing said dry processing liquid from said surface of said substrate after said operation c),
wherein said dry processing liquid has a lower surface tension than said rinse liquid,
a boiling point of said dry processing liquid is higher than a boiling point of said rinse liquid, and
said dry processing liquid that comes in contact with said surface of said substrate in said operation c) has a temperature that is a predetermined contact temperature higher than or equal to the boiling point of said rinse liquid and lower than the boiling point of said dry processing liquid.

2. The substrate processing method according to claim 1, further comprising:
e) removing molecules of said dry processing liquid adsorbed on said surface of said substrate by heating said substrate after said operation d).

3. The substrate processing method according to claim 2, wherein
said operation d) and said operation e) are conducted in one chamber.

4. The substrate processing method according to claim 1, further comprising:
supplying a substitution liquid to said surface of said substrate and replacing said rinse liquid that is in contact with said surface of said substrate with said substitution liquid between said operation b) and said operation c),
wherein, in said operation c), said dry processing liquid replaces said substitution liquid that is in contact with said surface of said substrate.

5. The substrate processing method according to claim 1, wherein
in said operation c), said dry processing liquid that is preheated to said contact temperature is supplied to said surface of said substrate.

6. The substrate processing method according to claim 1, wherein
in said operation c), a temperature of said dry processing liquid is increased to said contact temperature by heating said dry processing liquid that is in contact with said surface of said substrate.

7. The substrate processing method according to claim 1, wherein
a difference between said contact temperature and the boiling point of said dry processing liquid is less than or equal to 65° C.

8. The substrate processing method according to claim 1, wherein
in said operation c), a contact time of said dry processing liquid having said contact temperature with said surface of said substrate is 10 seconds or more.

9. The substrate processing method according to claim 1, wherein
said dry processing liquid contains fluorine-containing alcohol.

10. The substrate processing method according to claim 9, wherein
said fluorine-containing alcohol has —CF₂H at a terminal.

11. The substrate processing method according to claim 9, wherein
said fluorine-containing alcohol has —CF₃ at a terminal.

12. The substrate processing method according to claim 9, wherein
the number of carbons (C) contained in a molecular formula of said fluorine-containing alcohol is 4 or more.

13. A substrate processing apparatus for processing a substrate, comprising;
a chemical solution supplier that supplies a chemical solution to a surface of a substrate;
a rinse liquid supplier that supplies a rinse liquid to said surface of said substrate;
a dry processing liquid supplier that supplies a heated dry processing liquid to said surface of said substrate; and
a dry processing unit that dries said substrate by removing said dry processing liquid from said surface of said substrate,
wherein said dry processing liquid has a lower surface tension than said rinse liquid,
a boiling point of said dry processing liquid is higher than a boiling point of said rinse liquid, and
said dry processing liquid that comes in contact with said surface of said substrate has a temperature that is a predetermined contact temperature higher than or equal to the boiling point of said rinse liquid and lower than the boiling point of said dry processing liquid.

14. The substrate processing apparatus according to claim 13, wherein
said dry processing liquid contains fluorine-containing alcohol.

15. A dry processing liquid for use in substrate processing,
a substrate processing method using said dry processing liquid comprising:
a) supplying a chemical solution to a surface of a substrate;
b) supplying a rinse liquid to said surface of said substrate after said operation a);
c) bringing said dry processing liquid that is heated, into contact with said surface of said substrate after said operation b); and
d) drying said substrate by removing said dry processing liquid from said surface of said substrate after said operation c),
wherein said dry processing liquid contains fluorine-containing alcohol,
said dry processing liquid has a lower surface tension than said rinse liquid,
a boiling point of said dry processing liquid is higher than a boiling point of said rinse liquid, and
said dry processing liquid that comes in contact with said surface of said substrate in said operation c) has a temperature that is a predetermined contact temperature higher than or equal to the boiling point of said rinse liquid and lower than the boiling point of said dry processing liquid.
